(19) United States
(12) Patent Application Publication
(10) Pub. No.: US 2015/0295099 A1
(43) Pub. Date: Oct. 15, 2015

(54) HIGH WORK-FUNCTION BUFFER LAYERS FOR SILICON-BASED PHOTOVOLTAIC DEVICES

(71) Applicants: Kurtis Leschkies, Santa Clara, CA (US); Steven Verhaverbeke, San Francisco, CA (US); Roman Gouk, San Jose, CA (US); Robert Visser, Menlo Park, CA (US)

(72) Inventors: Kurtis Leschkies, Santa Clara, CA (US); Steven Verhaverbeke, San Francisco, CA (US); Roman Gouk, San Jose, CA (US); Robert Visser, Menlo Park, CA (US)

(21) Appl. No.: 14/371,702

(22) PCT Filed: Jan. 9, 2013
(86) PCT No.: PCT/US2013/020844

§ 371 Date: Jul. 10, 2014

Related U.S. Application Data
(60) Provisional application No. 61/586,550, filed on Jan. 13, 2012.

(51) Int. Cl. H01L 31/0288; H01L 31/028; H01L 31/0368; H01L 31/076; H01L 31/056; H01L 31/075; H01L 31/077; H01L 31/0224; H01L 31/0376

(52) U.S. Cl. CPC H01L 31/0288; H01L 31/022466; H01L 31/022475; H01L 31/022483; H01L 31/028; H01L 31/03682; H01L 31/03685; H01L 31/03762; H01L 31/056; H01L 31/075; H01L 31/077; H01L 31/076

(57) ABSTRACT

Embodiments of the invention generally provide a silicon-based photovoltaic (PV) device containing a high work-function (HWF) buffer layer disposed between a transparent conductive oxide (TCO) layer and a p-type silicon-based layer of a p-i-n junction. The PV device generally has a transparent substrate, a first TCO layer disposed on the transparent substrate, a HWF buffer layer disposed on the first TCO layer, a p-i-n junction disposed on the high work-function buffer layer, a second TCO layer disposed on the n-type silicon-based layer, and a metallic reflective layer disposed on the second TCO layer. The p-i-n junction contains an intrinsic layer disposed between a p-type silicon-based layer and an n-type silicon-based layer, and the p-type silicon-based layer is in contact with the HWF buffer layer.

### BACKGROUND OF THE INVENTION

1. Field of the Invention

Embodiments of the invention generally relate to photovoltaic devices, and more particularly relate to silicon-based photovoltaic devices having high work-function buffer layers.

2. Description of the Related Art

In solar, display, and touchscreen technologies, transparent conducting oxide (TCO) materials and layers are used as electrodes to provide low-resistance electrical contact to the active layers of a device while also allowing the passage of light to and from these layers. In single- and tandem-junction thin-film Si solar technologies, the electrical contact is made from the TCO layer to a p-i-n silicon junction. The p-i-n silicon junction generally contains layers of amorphous silicon (α-Si) and hydrogenated amorphous silicon (α-Si:H). In the p-i-n silicon junction, incident sunlight is absorbed wherein photogenerated electrons and holes are created, separated from one another, and finally transported to opposite collection electrodes to generate a photocurrent (e.g., TCO front contact to collect the holes and metal back contact to collect electrons). Since the mobility of photogenerated holes in α-Si is lower than that of electrons, typical device configurations place the p-layer of the p-i-n silicon junction in direct contact with the TCO layer in order to minimize the distance that the holes must travel to be collected. Similarly, the p-layer of the p-i-n silicon junction is also kept thin to shorten the travel distance of electrons. Furthermore, it is desirable for nearly all of the light absorption to take place in the intrinsic layer (i-layer) since charge transport and collection is so poor in the doped (e.g., p- and n-) layers of α-Si.

Incident sunlight must first contact and penetrate through the p-layer in α-Si (or p-doped region in other solar cell technologies) before arriving at the intrinsic layer. Therefore, it is desirable to minimize light absorption in the p-layer because any light absorption taking place in this layer is essentially lost. One promising strategy to minimize absorption losses in the p-layer is to widen the bandgap energy (E_{g}) by intentionally introducing carbon into the p-layer. An increased carbon content in the p-layer provides a raised bandgap energy and a reduced absorption of lower energy photons, which leads to higher photocurrents in the solar cell. Furthermore, a wider bandgap p-Si film also enhances the total built-in junction potential (V_{bi}), or photovoltage, in the overall device.

Unfortunately, carbon incorporation into the p-layer is generally limited because of an electronic barrier (e.g., Schottky barrier) that exists at the interface between the p-layer and the underlying TCO layer. Since photogenerated holes must transport across this barrier to produce a photocurrent (e.g., via a tunneling process), it is desirable to minimize the electronic barrier height (δ) of the barrier. However, the magnitude of the electronic barrier height is proportional to the carbon content in the p-layer. Therefore, the electronic barrier height for holes becomes larger as the carbon concentration increases in the p-layer. Therefore, while a wider bandgap p-layer is intended to generate higher photocurrents and photovoltages in solar cells, the wider bandgap p-layer also causes degradation of the fill factor in the PV cell, limiting the overall power conversion efficiency of the PV cell.

Therefore, there is a need for a PV cell with no electronic barrier or a substantially reduced electronic barrier at the interface between the TCO and the p-i-n junction and with an increased carbon concentration in the active p-layer of the p-i-n junction in order to maximize the photoelectric conversion efficiency.

### SUMMARY OF THE INVENTION

Embodiments of the invention generally provide methods for forming a silicon-based photovoltaic (PV) device containing a high work-function buffer layer disposed between a transparent conductive oxide (TCO) layer and a p-type silicon-based layer of a p-i-n junction. In one embodiment, a PV device is provided and has a first TCO layer disposed on a transparent substrate, a high work-function buffer layer disposed on the first TCO layer, a p-i-n junction disposed on the high work-function buffer layer, and a back reflector disposed on the p-i-n junction. The back reflector generally contains a second TCO layer disposed on an n-type silicon-based layer of the p-i-n junction and a metallic reflective layer disposed on the second TCO layer. The high work-function buffer layer is in contact with the p-type silicon-based layer and the first TCO layer.

The high work-function buffer layer contained in the PV device has a work-function equal to or greater than the work-function of the p-type silicon-based layer. Work-function is defined as the minimum energy required to either liberate an electron from a surface of a particular substance or move an electron from the Fermi level into vacuum. Generally, the work-function of the high work-function buffer layer is within a range from about 1% to about 50% greater than the work-function of the p-type silicon-based layer. In some examples, the work-function of the high work-function buffer layer is about 5 eV or greater, such as about 7 eV or greater, compared to the work-function of the p-type silicon-based layer which is about 5 eV or less, such as about 4 eV or less. Also, the electrical resistivity of the high work-function buffer layer is equal to or less than the electrical resistivity of the p-type silicon-based layer. Generally, the electrical resistivity of the high work-function buffer layer is less than 1% of the electrical resistivity of the p-type silicon-based layer. The electrical resistivity of the high work-function buffer layer is typically within a range from about 1×10¹ μΩ·cm to about 1×10¹¹ μΩ·cm, more narrowly within a range from about 1×10² μΩ·cm to about 1×10⁸ μΩ·cm. Additionally, the refractive index of the high work-function buffer layer is greater than the refractive index of the first TCO layer but less than the refractive index of the p-type silicon-based layer for a wavelength (λ) within a range from about 350 nm to about 2,000 nm.

The high work-function buffer layer contains at least one high work-function material selected from tungsten oxide, tungsten nitride, molybdenum oxide, molybdenum nitride, nickel oxide, nickel nitride, vanadium oxide, vanadium nitride, tungsten nickel oxide, gallium indium oxide, zinc tin oxide, zinc indium tin oxide, gallium indium tin oxide, derivatives thereof, alloys thereof, dopant variants thereof, or combinations thereof. In some examples, the high work-function buffer layer is a single layer or a bulk film, such as a layer or film containing vanadium oxide or nickel tungsten oxide. In other examples, the high work-function buffer layer is a multi-layered film (e.g., film stack or laminate) containing a plurality of layers, such as a film stack of tungsten oxide and tungsten nitride layers or a film stack of gallium indium oxide, zinc tin oxide, and tungsten oxide layers. In other examples, the high work-function buffer layer contains nanoparticles or nanowires, such as tungsten oxide nanoparticles or molybdenum nitride nanowires.

The p-i-n junction contains an intrinsic layer disposed between the p-type silicon-based layer and an n-type silicon-based layer. Generally, the intrinsic layer is a silicon-based intrinsic layer. Each of the p-type silicon-based layer, the n-type silicon-based layer, and the silicon-based intrinsic layer independently contains a silicon-based material, such as polycrystalline silicon (poly-Si), microcrystalline silicon (μc-Si), amorphous silicon (α-Si), hydrogenated amorphous silicon (α-Si:H), derivatives thereof, or combinations thereof. The TCO layer generally contains a metal oxide selected from zinc oxide, indium oxide, tin oxide, cadmium oxide, aluminum oxide, copper oxide, gallium oxide, tungsten oxide, molybdenum oxide, nickel oxide, vanadium oxide, tungsten nickel oxide, zinc tin oxide, derivatives thereof, alloys thereof, dopant variants thereof, or combinations thereof.

In other embodiments, a tandem-type PV device is provided and contains a first TCO layer disposed on a transparent substrate, a first high work-function buffer layer disposed on the first TCO layer, a first p-i-n junction disposed on the first high work-function buffer layer, a second TCO layer disposed on the first p-i-n junction, a second high work-function buffer layer disposed on the second TCO layer, a second p-i-n junction disposed on the second high work-function buffer layer, and a back reflector disposed on the second p-i-n junction. The back reflector generally contains a third TCO layer disposed on an n-type silicon-based layer of the second p-i-n junction and a metallic reflective layer disposed on the third TCO layer.

In one example, the first p-i-n junction contains an intrinsic layer disposed between a p-type silicon-based layer and an n-type silicon-based layer, and the p-type silicon-based layer in contact with the first high work-function buffer layer. In another example, the second p-i-n junction contains an intrinsic layer disposed between a p-type silicon-based layer and an n-type silicon-based layer, and the p-type silicon-based layer in contact with the second high work-function buffer layer.

In another embodiment, a method for fabricating or otherwise forming a silicon-based PV device is provided and includes depositing or forming a first TCO layer on a transparent substrate, depositing or forming a high work-function buffer layer on the first TCO layer, depositing or forming a p-i-n junction containing a p-type silicon-based layer on the high work-function buffer layer, wherein the work-function of the high work-function buffer layer is equal to or greater than the work-function of the p-type silicon-based layer, depositing or forming a second TCO layer on the p-i-n junction, and depositing or forming a metallic reflective layer on the second TCO layer.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts an exemplary cross-sectional view of a single-junction silicon-based PV cell, as described by some embodiments herein.

FIG. 2 depicts an exemplary cross-sectional view of a tandem junction silicon-based PV cell, as described by other embodiments herein.

FIG. 3 illustrates a dark band diagram of a solar cell containing a TCO/HWFL/p-layer interface formed by a high work-function buffer layer disposed between a TCO layer and a Si-based p-i-n junction, as described by embodiments herein.

FIG. 4 illustrates a dark band diagram of a solar cell containing a TCO/p-layer interface formed between a TCO layer and a Si-based p-i-n junction, as described in a comparison example.

FIGS. 5A-5C depict exemplary cross-sectional views of tandem junction silicon-based PV cells, as described by alternative embodiments herein.

### DETAILED DESCRIPTION

Embodiments of the invention generally provide silicon-based photovoltaic (PV) devices, such as solar or PV cells, which contain a high work-function buffer layer disposed between a transparent conductive oxide (TCO) layer and a Si-based p-i-n junction to provide a TCO/HWFL/p-layer interface. The high work-function buffer layer eliminates or substantially reduces the electronic barrier (e.g., Schottky barrier) at the TCO/HWFL/p-layer interface in the PV cell, relative to the electronic barrier at the TCO/p-layer interface within a PV cell lacking the high work-function buffer layer. The elimination or substantial reduction of the electronic barrier enables the use of p-type materials in the p-layer which have higher carbon concentrations and a wider bandgap energy without sacrificing the fill factor. The fill factor is a parameter utilized to evaluate the performance of solar cells and is determined as the ratio of the actual maximum obtainable power over the product of the open circuit voltage and short circuit current. The silicon-based PV devices generally have p-i-n junctions which may contain doped and/or non-doped silicon-based materials which include amorphous silicon (α-Si), hydrogenated amorphous silicon (α-Si:H), polycrystalline silicon (poly-Si), and/or microcrystalline silicon (μc-Si).

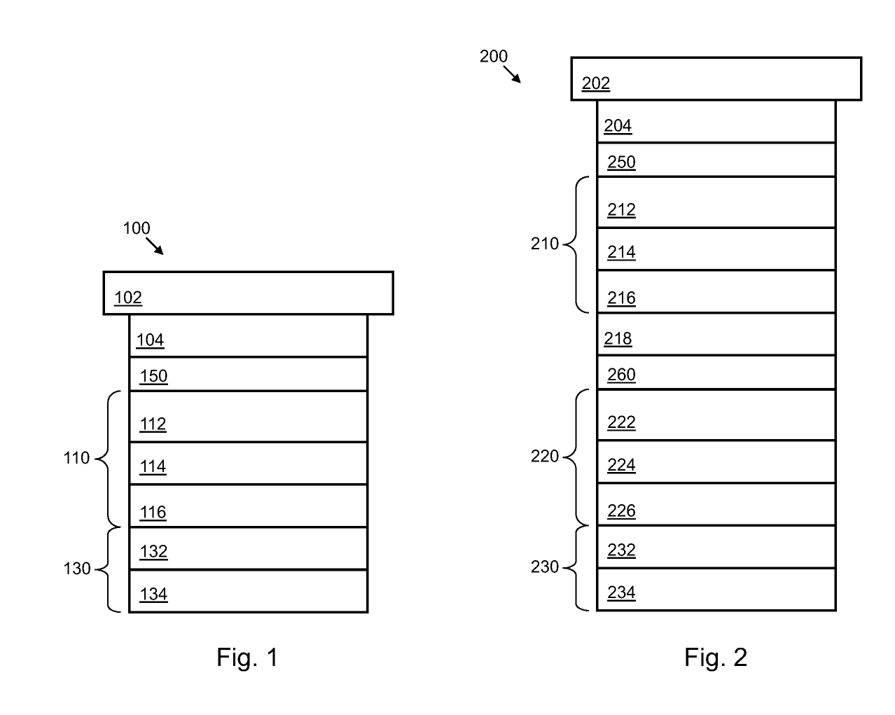

FIG. 1 depicts an exemplary cross-sectional view of a single-junction, photovoltaic cell, such as photovoltaic (PV) cell 100, in accordance with embodiments described herein. The PV cell 100 is generally a silicon-based thin film PV cell and may be fabricated, manufactured, or otherwise formed by the processes described herein. The PV cell 100 has a front window, such as the transparent substrate 102, and contains a TCO layer, such as a TCO layer 104 disposed on the transparent substrate 102. Additionally, the PV cell 100 has a HWF buffer layer 150 disposed on the TCO layer 104, a p-i-n junction 110 disposed on the HWF buffer layer 150, and a back reflector 130 disposed on the p-i-n junction 110. The p-i-n junction 110 contains a p-type Si-based layer 112, an intrinsic type (i-type) Si-based layer 114, and an n-type Si-based layer 116, as illustrated in FIG. 1.

Additionally, the back reflector 130 contains a TCO layer 132 and a metallic reflective layer 134. The back reflector 130 is formed on or over the p-i-n junction 110 of the PV cell 100. In some embodiments, a TCO layer 132 is formed on the n-type Si-based layer 116 of the p-i-n junction 110 and thereafter, the metallic reflective layer 134 is formed on the TCO layer 132 to fabricate or otherwise form the back reflector 130. In other embodiments, the metallic reflective layer 134 is deposited or formed directly on the p-i-n junction 110 while fabricating the back reflector 130 without an additional TCO layer, such as the TCO layer 132. The PV cell 100 contains a TCO/HWFL/p-layer interface formed by a high work-function (HWF) buffer layer 150 disposed between a TCO layer 104 and a p-i-n junction 110, as described by embodiments herein.

The transparent substrate 102 is utilized as the front window of the PV cell 100. The transparent substrate 102 may be a pane or a thin sheet of transparent material, such as glass, quartz, silicon, silicon oxide, plastic or polymeric material (e.g., polycarbonate), or other suitable material. In one example, the transparent substrate 102 is a glass substrate. The transparent substrate 102 may have a surface area greater than about 0.1 m², such as greater than about 1 m², and greater than about 2 m². It is to be understood that the transparent substrate 102 may be referred to as a ‘superstrate’ in which the solar cell is fabricated from the top down. During fabrication, the transparent substrate 102 is typically referred to as a substrate, but then referred to as a ‘superstrate’ once the final product is flipped over to face the transparent substrate 102 towards the sun. In some embodiments, the fabricated PV cell has a similar configuration as the PV cell 100 such that the transparent substrate 102 is facing towards the sun and contains transparent materials. In alternative embodiments, the fabricated PV cell has a different configuration as the PV cell 100 such that the transparent substrate 102 is facing away from the sun and may contain non-transparent materials.

The PV cell 100 contains a p-i-n device or junction, such as the p-i-n junction 110—which is deposited or otherwise formed on the TCO layer 104 disposed on the transparent substrate 102. The HWF buffer layer 150 is deposited or otherwise formed on the TCO layer 104, and subsequently, the p-i-n junction 110 is formed on or over the HWF buffer layer 150. The p-i-n junction 110 includes p-type Si-based layer 112, n-type Si-based layer 116, and an intrinsic type (i-type) Si-based layer 114 disposed between the p-type Si-based layer 112 and the n-type Si-based layer 116—as a photoelectric conversion layer—for providing electrical emission from photon absorption.

An optional dielectric layer (not shown) may be disposed between the transparent substrate 102 and the TCO layer 104. In some examples, the optional dielectric layer is a silicon-based layer containing amorphous or polysilicon, silicon oxynitride, silicon nitride, silicon carbide, silicon oxycarbide, silicon oxide layer, doped silicon layer, or other suitable silicon-containing layer. In other examples, the optional dielectric layer contains a titanium-based material, such as titanium oxide, that provides a barrier to impurities/dopants contained within the transparent substrate 102.

The TCO layer 104 may contain and/or be fabricated from a metal oxide, or a mixture of metal oxides, which is electrically conductive and transparent. The TCO layer 104 may also contain a metal selenide, a metal telluride, or a mixture thereof that is electrically conductive and transparent. The metal oxides or other materials of the TCO layer 104 may contain zinc, indium, tin, cadmium, aluminum, copper, gallium, alloys thereof, mixtures thereof, or combinations thereof. The metal oxides include stoichiometric metal oxides, non-stoichiometric metal oxides, or mixtures thereof. Exemplary metal oxides, metal selenides, or metal tellurides which may be contained within the TCO layer 104 include zinc oxide (e.g., ZnO), indium oxide (In₂O₃), tin oxide (e.g., SnO₂), zinc tin oxide, indium tin oxide (ITO), cadmium oxide (CdO), cadmium stannate (e.g., Cd₂SnO₄), aluminum oxide or alumina (e.g., Al₂O₃), copper oxide, tungsten oxide, molybdenum oxide, nickel oxide, vanadium oxide, tungsten nickel oxide, gallium oxide, copper indium gallium selenide (CIGS—e.g., CuIn₁₋ₓGaₓSe₂-based materials, where x is within a range from about 0.001 to about 0.999), cadmium telluride (e.g., CdSe-based materials), doped materials thereof, derivatives thereof, alloys thereof, or combinations thereof. The TCO layer 104 may contain TCO materials that include additional dopants or elements, such as aluminum, gallium, boron, fluorine, sulfur, selenium, tellurium, or mixtures thereof. In some examples, the TCO layer 104 may contain zinc oxide with a dopant concentration of about 5 at % (atomic percent) or less, such as about 2.5 at % or less. In some examples, the TCO layer 104 may contain and/or be fabricated from a zinc oxide layer having a desired aluminum oxide or alumina dopant concentration formed within the zinc oxide layer. In one example, the TCO layer 104 may be doped and have zinc oxide containing aluminum at a concentration of about 2.5 at %. In another example, the TCO layer 104 may be doped and have tin oxide containing a dopant of fluorine. The TCO layer 104 generally has a thickness within a range from about 1,000 Å (1 μm) to about 20,000 Å (20 μm), more narrowly within a range from about 5,000 Å (5 μm) to about 10,000 Å (10 μm), and more narrowly within a range from about 7,000 Å (7 μm) to about 12,000 Å (12 μm).

The TCO layer 104 may be deposited or otherwise formed by a physical vapor deposition (PVD) process, an electroless chemical deposition/plating process, a chemical vapor deposition (CVD) process, a plasma enhanced chemical vapor deposition (PE-CVD) process, or other deposition processes. In many examples, the TCO layer 104 is fabricated by a sputter deposition process, wherein the TCO material is either sputtered from a metal oxide target or sputtered from a metallic target within an oxidizing environment, such as a chamber containing oxygen, ozone, or other oxidizing agent. In some examples, the transparent substrate 102 may be provided by a supplier (e.g., glass manufacturer) with the TCO layer 104 already provided thereon. Several PVD processes which may be used to fabricate the TCO layer 104 are further described in commonly assigned U.S. application Ser. Nos. 12/748,780 and 12/748,790, both filed Mar. 29, 2010, and respectively published as U.S. Pub. Nos. 2010-0311228 and 2010-0311204, which are incorporated herein by reference.

The HWF buffer layer 150 is disposed between the TCO layer 104 and the p-type Si-based layer 112 of the p-i-n junction 110. The HWF buffer layer 150 is deposited, plated, or otherwise formed on the TCO layer 104, and subsequently, the p-i-n junction 110 is formed on or over the HWF buffer layer 150. If the HWF buffer layer 150 was omitted from the PV cell 100, a Schottky/electronic barrier would exist at the TCO/p-layer interface—therebetween the TCO layer 104 and the p-type Si-based layer 112. However, the HWF buffer layer 150 is disposed within the TCO/p-layer interface to form a TCO/HWFL/p-layer interface, wherein the HWF buffer layer 150 is a high work-function layer (HWFL). Therefore, the electronic barrier at the TCO/HWFL/p-layer interface is eliminated or substantially reduced in the PV cell 100 containing the HWF buffer layer 150, relative to the electronic barrier at the TCO/p-layer interface within a PV cell lacking the HWF buffer layer 150. The elimination or substantial reduction of the electronic barrier at the TCO/HWFL/p-layer interface enables the use of wider bandgap p-layer materials contained within the p-type Si-based layer 112. Also, the elimination or substantial reduction of the electronic barrier at the TCO/HWFL/p-layer interface in the PV cell 100 provides for the use of higher carbon concentrations within the p-type materials contained within the p-type Si-based layer 112. Generally, the p-type materials that have a higher carbon concentration also have a wider bandgap energy without sacrificing the fill factor of the PV cell 100.

The HWF buffer layer 150 contains one or more high work-function materials. The high work-function materials provide the HWF buffer layer 150 with the following desired properties: (i) high work-function (e.g., <4.5 eV), (ii) optical transparency, (iii) electrical conductivity, and (iv) resistance to H₂ plasma. Generally, the high work-function materials may be stoichiometric and/or non-stoichiometric metal oxides, metal nitrides, metal oxynitrides, or mixtures thereof. Exemplary high work-function materials contained within the HWF buffer layer 150 include tungsten oxide, tungsten nitride, molybdenum oxide, molybdenum nitride, nickel oxide, nickel nitride, vanadium oxide, vanadium nitride, tungsten nickel oxide, gallium indium oxide, zinc tin oxide, zinc indium tin oxide, gallium indium tin oxide, derivatives thereof, alloys thereof, dopant variants thereof, or combinations thereof.

The HWF buffer layer 150 may exist in a variety of morphologies, such as a single layer or a bulk film, as well as multi-layered films, laminate films, film stacks, nanoparticles, and nanowires. Therefore, the HWF buffer layer 150 is deposited or otherwise formed on the TCO layer 104 by a variety of different processes including vapor deposition processes, such as CVD, ALD, PVD, or evaporation, and solution-based deposition or plating processes, such as electroless deposition and electrochemical plating. The HWF buffer layer 150 generally has a thickness within a range from about 1 Å to about 1,000 Å (1 μm), more narrowly within a range from about 20 Å to about 100 Å.

In one embodiment, the HWF buffer layer 150 contains a single layer or a bulk film of a high work-function material. In one example, the HWF buffer layer 150 contains vanadium oxide. In another example, the HWF buffer layer 150 contains nickel tungsten oxide. In other embodiments, the HWF buffer layer 150 is a multi-layered film, such as a laminate film or a film stack, and contains a plurality of layers of high work-function materials. Each of the layers within the multi-layered film may independently contain the same material or a different material as the other layers therein. The HWF buffer layer 150 as a multi-layered film may have 2 layers, 3 layers, 4 layers, 5 layers, or more layers. In some examples, the HWF buffer layer 150 contains a layer of tungsten oxide and a layer of tungsten nitride, for example, a tungsten oxide layer disposed on a tungsten nitride layer. In other examples, the HWF buffer layer 150 contains a layer of gallium indium oxide, a layer of zinc tin oxide, and a layer of tungsten oxide, for example, a gallium indium oxide layer disposed on a zinc tin oxide layer disposed on a tungsten oxide layer.

In other embodiments, the HWF buffer layer 150 contains nanoparticles or nanowires containing one or more of the high work-function materials. The HWF buffer layer 150 may contain nanoparticles having a particle size within a range from about 1 nm to about 500 nm. The HWF buffer layer 150 generally has a surface density of nanoparticles within a range from about 10 particles/μm² to about 100 particles/μm². In some examples, the HWF buffer layer 150 contains nanoparticles of tungsten oxide, vanadium oxide, or nickel tungsten oxide. Alternatively, the HWF buffer layer 150 contains nanowires having a diameter within a range from about 25 nm to about 500 nm and a length within a range from about 500 nm to about 10,000 nm (about 10 μm). The HWF buffer layer 150 generally has a surface density of the nanowires within a range from about 10 wires/μm² to about 100 wires/μm². In some examples, the HWF buffer layer 150 contains nanowires of tungsten nitride or nickel nitride.

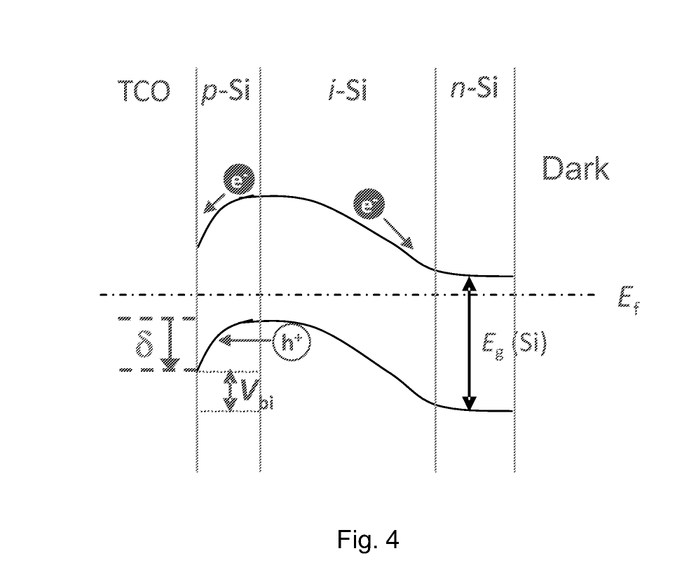

FIG. 3 illustrates a dark band diagram of a solar cell, such as the PV cell 100, in which a HWFL, the HWF buffer layer 150, is disposed between a TCO layer and a Si-based p-i-n junction layer, such as between the TCO layer 104 and the p-i-n junction 110. Shown are vacuum levels, conduction and valence bands, work-functions (φ), Fermi levels (E_{f}), bandgap energies (E_{g}), total built-in potential (V_{bi}) in the PV cell 100, and desired flow directions of charges that produce a photocurrent. The HWF buffer layer 150 enhances the performance of the PV cell 100, as opposed to a solar cell lacking a HWFL, such as by shielding the low work-function (φ) of the TCO layer 104, from the layers of the p-i-n junction 110. This enhancement by the HWF buffer layer 150 pushes both the Fermi level and valence and conduction bands of the p-type material within the p-type Si-based layer 112 upwards in a direction to resemble ohmic contact as opposed to a Schottky/electronic barrier, as illustrated in FIG. 3.

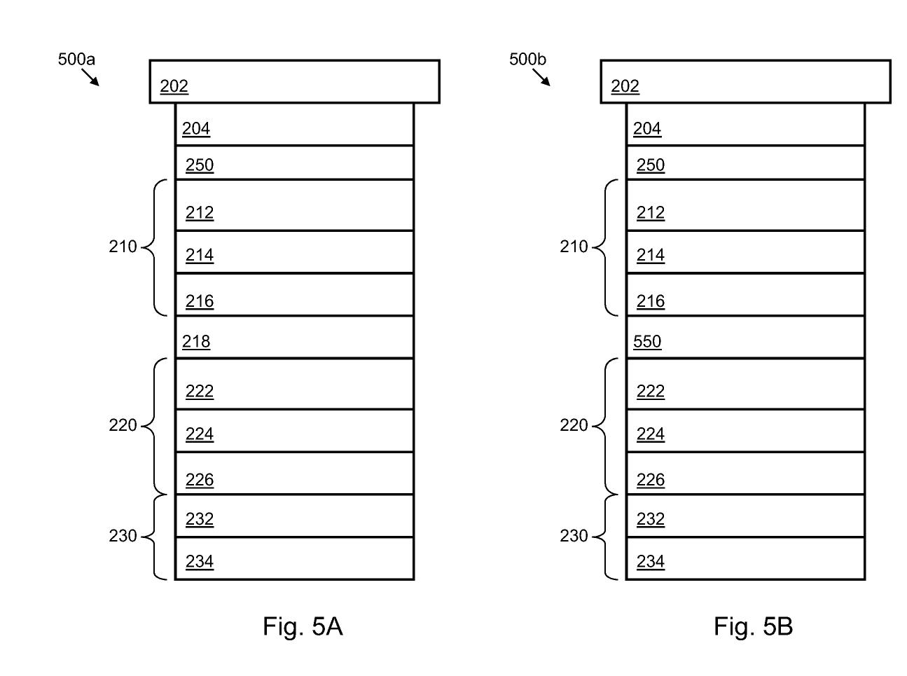

For comparison, a solar or PV cell lacking a HWFL (e.g., similar to the PV cell 100 omitting the HWF buffer layer 150) therefore has a TCO/p-Si interface. FIG. 4 depicts a dark band diagram of a solar cell in which a TCO is contacted with a Si-based p-i-n junction layer. Shown are vacuum levels, conduction and valence bands, Fermi levels (E_{f}), bandgap energies (E_{g}), total built-in potential (V_{bi}) in the PV cell 100, the electronic barrier height (δ), and desired flow directions of charges that produce a photocurrent. The electronic barrier that exists at the TCO/p-Si interface is due to a work-function mismatch that exists between the p-i-n Si junction and the TCO layer. The low work-function of the TCO layer pulls both the Fermi level (E_{f}) and valence and conduction bands of the p-Si layer in the direction opposite to that of an ohmic contact when the TCO and p-Si layers are placed into intimate contact with each other. Consequently, the formation of a Schottky/electronic barrier follows. However, in the PV cell 100 containing the HWF buffer layer 150, the electronic barrier has been eliminated or substantially reduced due to the contact between the p-type Si-based layer 112 and high work-function material of the HWF buffer layer 150.

The work-function (φ) of the HWF buffer layer 150 is equal to, substantially equal to, or greater than the work-function of the p-type Si-based layer 112. The work-function of the HWF buffer layer 150 is generally within a range from about 1% to about 50% greater than the work-function of the p-type Si-based layer 112. In many examples, the work-function of the HWF buffer layer 150 is about 5 eV or greater and the work-function of the p-type Si-based layer 112 is about 5 eV or less. Typically, the work-function of the p-type Si-based layer 112 is within a range from about 4 eV to about 5 eV. Therefore, the work-function of the HWF buffer layer 150 is usually greater than 4.5 eV, such as 4.8 eV or greater and is generally within a range from about 4.8 eV to about 8 eV, more narrowly within a range from about 5 eV to about 7 eV, and more narrowly within a range from about 5.25 eV to about 6.5 eV. In some examples, the work-function of the HWF buffer layer 150 is about 5.15 eV.

Also, the electrical resistivity of the HWF buffer layer 150 is equal to, substantially equal to, or less than the electrical resistivity of the p-type Si-based layer 112, generally, the electrical resistivity of the HWF buffer layer 150 is less than 1% of the electrical resistivity of the p-type Si-based layer 112. The electrical resistivity of the HWF buffer layer 150 is typically about 1×10¹¹ μΩ·cm or less, such as within a range from about 1×10¹ μΩ·cm to about 1×10¹¹ μΩ·cm, more narrowly within a range from about 1×10² μΩ·cm to about 1×10⁸ μΩ·cm.

In some examples, the resistivity of a film containing the TCO layer 104 and the HWF buffer layer 150 is increased by about 5% or less, relative to the resistivity of the same TCO layer 104 alone (e.g., same composition and thickness). Also, the mobility of a film containing the TCO layer 104 and the HWF buffer layer 150 is decreased by about 5% or less, relative to the mobility of the same TCO layer 104 alone. Additionally, the roughness of a film containing the TCO layer 104 and the HWF buffer layer 150 is reduced by about 10% or less, relative to the roughness of the same TCO layer 104 alone. In other examples, the HWF buffer layer 150 adheres to and is in contact with an adjacent silicon-based layer or material, such as the p-type Si-based layer 112, wherein no delamination or substantially no delamination occurs between the HWF buffer layer 150 and the adjacent silicon-based layer or material (e.g., the p-type Si-based layer 112). In other examples, the HWF buffer layer 150 is resistant to or substantially resistant to the exposure of a chemically reducing plasma (e.g., hydrogen plasma) such that no transmission losses or substantially no transmission losses are attributed to the HWF buffer layer 150 post plasma exposure.

The HWF buffer layer 150 may have a refractive index (n) greater than the refractive index of the TCO layer 104 and less than the refractive index of the p-type Si-based layer 112, such that n_{TCO}<n<n_{p-Si}, for a wavelength (λ) within a range from about 350 nm to about 2,000 nm. Generally, the refractive index of the HWF buffer layer 150 is within a range from about 1% to about 125% greater than the refractive index of the first transparent metal oxide layer for a wavelength (λ) within a range from about 350 nm to about 2,000 nm. Also, the refractive index of the HWF buffer layer 150 is usually within a range from about 1% to about 55% less than the refractive index of the p-type silicon-based layer for a wavelength (λ) within a range from about 350 nm to about 2,000 nm. Therefore, the refractive index of the HWF buffer layer 150 is within a range from about 1.5 to about 4.5 for a wavelength (λ) within a range from about 350 nm to about 2,000 nm.

The absorption coefficient (α) of the HWF buffer layer 150 is less than the absorption coefficient of the TCO layer 104 for a wavelength (λ) within a range from about 350 nm to about 2,000 nm. The absorption coefficient of the HWF buffer layer 150 is no less than 1% of the absorption coefficient of the TCO layer 104 for a wavelength (λ) within a range from about 350 nm to about 2,000 nm. The absorption coefficient of the HWF buffer layer 150 is typically within a range from about 1×10⁻² cm⁻¹ to about 1×10⁶ cm⁻¹, more narrowly within a range from about 1×10⁻¹ cm⁻¹ to about 1×10⁵ cm⁻¹, for a wavelength (λ) within a range from about 350 nm to about 2,000 nm. The HWF buffer layer 150 may have a transmission value of about 95% or greater, such as about 96% or greater, such as about 97% or greater, such as about 98% or greater, such as about 99% or greater, for example, about 99.5% or greater for a wavelength (λ) within a range from about 350 nm to about 2,000 nm.

The p-type Si-based layer 112 contains a silicon-based material such as amorphous silicon (α-Si), polycrystalline silicon (poly-Si), microcrystalline silicon (μc-Si), or combinations thereof, which is doped by a Group III element. In many examples, the silicon-based materials contained within the p-type Si-based layer 112 are amorphous silicon materials. The silicon-based material, layer, or film doped with the Group III element is referred to as a p-doped or a p-type silicon material, layer, or film. The p-type Si-based layer 112 also contains at least one dopant element and may contain two or more dopant elements, such as boron, gallium, carbon, or combinations thereof. In many examples, the p-type Si-based layer 112 contains a boron-doped, amorphous silicon material or a boron-doped, carbon-doped, amorphous silicon material. Alternatively, the p-type Si-based layer 112 may be doped with other elements selected to meet device requirements of the PV cell 100. In some examples, the p-type Si-based layer 112 contains a silicon-based material doped with carbon and has a carbon concentration within a range from about 0.01 at % to about 50 at %, more narrowly within a range from about 0.1 at % to about 20 at %, more narrowly within a range from about 1 at % to about 10 at %, and more narrowly within a range from about 2 at % to about 5 at %. The p-type Si-based layer 112 is generally deposited by CVD or PE-CVD. The p-type Si-based layer 112 generally has a thickness within a range from about 1 Å to about 500 Å, more narrowly within a range from about 10 Å to about 200 Å, and more narrowly within a range from about 20 Å to about 50 Å.

The intrinsic Si-based layer 114 is a non-doped type silicon based film disposed between the p-type Si-based layer 112 and the n-type Si-based layer 116. The intrinsic Si-based layer 114 is deposited under process conditions controlled to provide film properties having improved photoelectric conversion efficiency of the PV cell 100. In many examples, the intrinsic Si-based layer 114 contains and is fabricated from an intrinsic (i-type) material, such as i-type polycrystalline silicon (poly-Si), i-type microcrystalline silicon (μc-Si), amorphous silicon (α-Si), or hydrogenated amorphous silicon (α-Si:H). The intrinsic Si-based layer 114 generally has a thickness within a range from about 100 Å and about 100,000 Å (100 μm) depending on the application and the type of silicon-based material. In one embodiment, the intrinsic Si-based layer 114 contains amorphous silicon and has a thickness within a range from about 100 Å to about 10,000 Å (10 μm), more narrowly within a range from about 200 Å to about 8,000 Å (8 μm), and more narrowly within a range from about 1,000 Å (1 μm) to about 5,000 Å (5 μm). In another embodiment, the intrinsic Si-based layer 114 contains microcrystalline silicon and has a thickness within a range from about 1,000 Å (1 μm) to about 100,000 Å (100 μm), more narrowly within a range from about 2,000 Å (2 μm) to about 80,000 Å (80 μm), and more narrowly within a range from about 10,000 Å (10 μm) to about 50,000 Å (50 μm).

The n-type Si-based layer 116 contains a silicon-based material such as amorphous silicon (α-Si), polycrystalline silicon (poly-Si), microcrystalline silicon (μc-Si), or combinations thereof, which is doped by a Group V element. In many examples, the n-type Si-based layer 116 contains n-doped amorphous silicon. The silicon-based material, layer, or film doped with the Group V element is referred to as an n-doped or an n-type silicon material, layer, or film. The n-type Si-based layer 116 also contains at least one dopant element and may contain two or more dopant elements, such as phosphorous, arsenic, or combinations thereof. In one example, the n-type Si-based layer 116 contains a phosphorus doped, amorphous silicon material. Alternatively, the n-type Si-based layer 116 may be doped with other elements selected to meet device requirements of the PV cell 100. The n-type Si-based layer 116 is generally deposited by CVD or PE-CVD. The n-type Si-based layer 116 typically has a thickness within a range from about 1 Å to about 500 Å, more narrowly within a range from about 10 Å to about 200 Å, and more narrowly within a range from about 30 Å to about 70 Å.

Å back reflector 130 is fabricated or otherwise formed on or over the p-i-n junction 110. In some embodiments, the back reflector 130 contains a metallic reflective layer 134 disposed on or over a TCO layer 132, as depicted in FIG. 1. The TCO layer 132 is deposited or otherwise formed on the p-i-n junction 110, such as on the n-type Si-based layer 116. Thereafter, the metallic reflective layer 134 is deposited or otherwise formed on the TCO layer 132. In an alternative embodiment, the back reflector 130 contains the metallic reflective layer 134 disposed directly on the p-i-n junction 110 without containing an additional TCO layer, such as the TCO layer 132 (not shown).

The TCO layer 132 may be independently fabricated or contain the same material or a different material as the TCO layer 104. The TCO layer 132 may contain a metal oxide, a mixture of metal oxides, a metal selenide, a metal telluride, or a mixture thereof that is electrically conductive and transparent. The metal oxides or other materials of the TCO layer 132 may contain zinc, indium, tin, cadmium, aluminum, copper, gallium, alloys thereof, mixtures thereof, or combinations thereof. The metal oxides include stoichiometric metal oxides, non-stoichiometric metal oxides, or mixtures thereof. Exemplary metal oxides, metal selenides, or metal tellurides which may be contained within the TCO layer 132 include zinc oxide (e.g., ZnO), indium oxide (In₂O₃), tin oxide (e.g., SnO₂), zinc tin oxide, indium tin oxide (ITO), cadmium oxide (CdO), cadmium stannate (e.g., Cd₂SnO₄), aluminum oxide or alumina (e.g., Al₂O₃), copper oxide, tungsten oxide, molybdenum oxide, nickel oxide, vanadium oxide, tungsten nickel oxide, gallium oxide, copper indium gallium selenide (CIGS—e.g., CuIn₁₋ₓGaₓSe₂-based materials, where x is within a range from about 0.001 to about 0.999), cadmium telluride (e.g., CdSe-based materials), doped materials thereof, derivatives thereof, alloys thereof, or combinations thereof.

The TCO layer 132 may contain TCO materials that include additional dopants or elements, such as aluminum, gallium, boron, fluorine, sulfur, selenium, tellurium, or mixtures thereof. In some examples, the TCO layer 132 may contain zinc oxide with a dopant concentration of about 5 at % (atomic percent) or less, such as about 2.5 at % or less. In some examples, the TCO layer 132 may contain and/or be fabricated from a zinc oxide layer having a desired aluminum oxide or alumina dopant concentration formed within the zinc oxide layer. In one example, the TCO layer 132 may be doped and have zinc oxide containing aluminum at a concentration of about 2.5 at %. In another example, the TCO layer 132 may be doped and have tin oxide containing a dopant of fluorine. The TCO layer 132 generally has a thickness within a range from about 1,000 Å (1 μm) to about 20,000 Å (20 μm), more narrowly within a range from about 5,000 Å (5 μm) to about 10,000 Å (10 μm), and more narrowly within a range from about 7,000 Å (7 μm) to about 12,000 Å (12 μm).

The TCO layer 132 may be deposited or otherwise formed by a PVD process, an electroless chemical deposition/plating process, a CVD process, a PE-CVD process, or other deposition processes. In many examples, the TCO layer 132 is fabricated by a sputter deposition process, wherein the TCO material is either sputtered from a metal oxide target or sputtered from a metallic target within an oxidizing environment, such as a chamber containing oxygen, ozone, or other oxidizing agent. In some examples, the transparent substrate 102 may be provided by a supplier (e.g., glass manufacturer) with the TCO layer 132 already provided thereon. Several PVD processes which may be used to fabricate the TCO layer 132 are further described in commonly assigned U.S. application Ser. Nos. 12/748,780 and 12/748,790, both filed Mar. 29, 2010, and respectively published as U.S. Pub. Nos. 2010-0311228 and 2010-0311204, which are incorporated herein by reference.

The metallic reflective layer 134 contained within back reflector 130 may be deposited or otherwise formed on or over the TCO layer 132. The metallic reflective layer 134 may be formed by a PVD process, a CVD process, a PE-CVD process, an electrochemical deposition process, an electroless deposition process, or a combination of two or more deposition or plating processes. The metallic reflective layer 134 may contain or be made from at least one metal, such as titanium, chromium, aluminum, nickel, silver, gold, copper, platinum, palladium, ruthenium, alloys thereof, or combinations thereof.

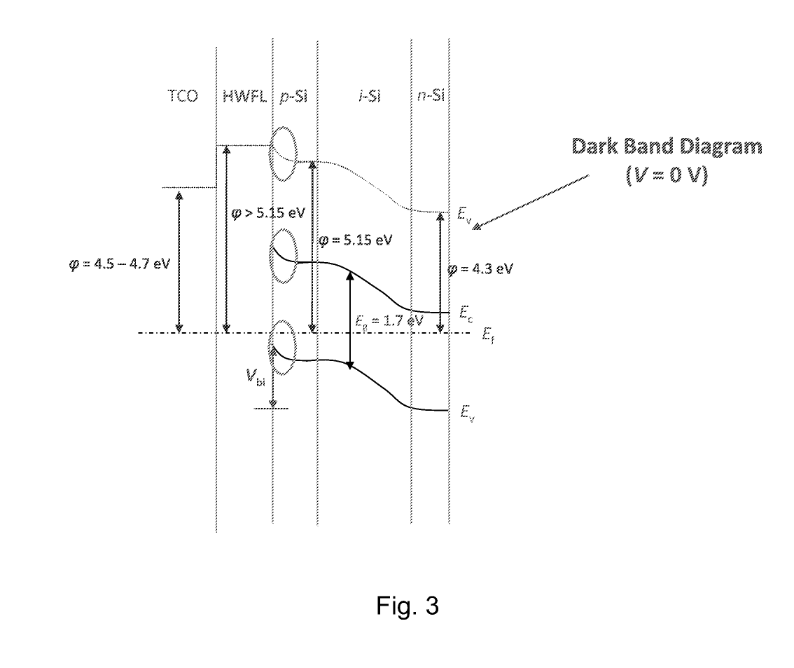

FIG. 2 depicts an exemplary cross-sectional view of a tandem-type photovoltaic (PV) cell 200 fabricated in accordance with other embodiments described herein. Portions of the tandem-type PV cell 200 may have similar structures and/or materials as the PV cell 100—however—the tandem-type PV cell 200 contains at least two high work-function layers (HWFLs), such as high work-function buffer layers 250 and 260, and therefore has at least two TCO/HWFL/p-layer interfaces, as depicted in FIG. 2. However, alternative embodiments provide tandem-type PV cells that have a single HWFL, similar to the tandem-type PV cell 200, but lacking the HWF buffer layer 260.

Similar to the PV cell 100, the tandem-type PV cell 200 contains a transparent conductive oxide (TCO) layer 204 disposed on a transparent substrate 202, a high work-function (HWF) buffer layer 250 disposed on the TCO layer 204, and a first p-i-n junction 210 disposed on the HWF buffer layer 250. The first p-i-n junction 210 may contain the same type or different types of layers and/or materials as described with reference to the p-i-n junction 110 of the PV cell 100 depicted in FIG. 1, such as the doped and non-doped silicon-based materials which include amorphous silicon (α-Si), hydrogenated amorphous silicon (α-Si:H), polycrystalline silicon (poly-Si), and/or microcrystalline silicon (μc-Si).

Additionally, the tandem-type PV cell 200 has an intermediate TCO layer 218 disposed on the first p-i-n junction 210, a high work-function (HWF) buffer layer 260 disposed on the intermediate TCO layer 218, a second p-i-n junction 220 disposed on the HWF buffer layer 260, and a back reflector 230 disposed over the second p-i-n junction 220, as depicted in FIG. 2. The second p-i-n junction 220 may contain the same type or different types of layers and/or materials as described with reference to the first p-i-n junction 210 and/or the p-i-n junction 110.

In one embodiment, the tandem-type PV cell 200 may be a silicon-based thin film photovoltaic cell having a front window, such as the transparent substrate 202, as described in one embodiment herein. In some examples, the tandem-type PV cell 200 is an α-Si/μc-Si-based tandem junction solar cell—such that the first p-i-n junction 210 contains an α-Si-based junction and the second p-i-n junction 220 contains a μc-Si-based junction.

FIG. 2 illustrates the first p-i-n junction 210 containing a p-type Si-based layer 212, an intrinsic Si-based layer 214, and an n-type Si-based layer 216, the second p-i-n junction 220 containing a p-type Si-based layer 222, an intrinsic Si-based layer 224, and an n-type Si-based layer 226, as well as the back reflector 230 containing a TCO layer 232 and a metallic reflective layer 234. In some embodiments, the intermediate TCO layer 218 is deposited or otherwise formed on or over the n-type Si-based layer 216 of the first p-i-n junction 210. Thereafter, the HWF buffer layer 260 is deposited or otherwise formed on or over the intermediate TCO layer 218 and the p-type Si-based layer 222 is deposited or otherwise formed on or over the HFW buffer layer 260. The back reflector 230 is deposited or otherwise formed on or over the second p-i-n junction 220 of the tandem-type PV cell 200. In some embodiments, the TCO layer 232 is deposited or otherwise formed on or over the n-type Si-based layer 226 of the second p-i-n junction 220. Thereafter, the metallic reflective layer 234 is deposited or otherwise formed on or over the TCO layer 232 to complete assembly of the back reflector 230.

The PV cell 200 has a front window, such as the transparent substrate 202, which may be a pane or a thin sheet of transparent material, such as glass, quartz, silicon, silicon oxide, plastic or polymeric material (e.g., polycarbonate), or other suitable material. In one embodiment, the transparent substrate 202 is a transparent substrate. The transparent substrate 202 may have a surface area greater than about 0.1 m², such as greater than about 1 m², and greater than about 2 m². It is to be understood that the transparent substrate 202 may be referred to as a ‘superstrate’ in which the solar cell is fabricated from the top down. During fabrication, the transparent substrate 202 is typically referred to as a substrate, but then referred to as a ‘superstrate’ once the final product is flipped over to face the transparent substrate 202 towards the sun. In some embodiments, the fabricated PV cell has a similar configuration as the PV cell 200 such that the transparent substrate 202 is facing towards the sun and contains transparent materials. In alternative embodiments, the fabricated PV cell has a different configuration as the PV cell 200 such that the transparent substrate 202 is facing away from the sun and may contain non-transparent materials.

An optional dielectric layer (not shown) may be disposed between the transparent substrate 202 and the TCO layer 204. In some examples, the optional dielectric layer is a silicon-based layer containing amorphous or polysilicon, silicon oxynitride, silicon nitride, silicon carbide, silicon oxycarbide, silicon oxide layer, doped silicon layer, or other suitable silicon-containing layer. In other examples, the optional dielectric layer contains a titanium-based material, such as titanium oxide, that provides a barrier to impurities/dopants contained within the transparent substrate 202.

The TCO layer 204 may contain and/or be fabricated from a metal oxide, or a mixture of metal oxides, which is electrically conductive and transparent. The TCO layer 204 may also contain a metal selenide, a metal telluride, or a mixture thereof that is electrically conductive and transparent. The metal oxides or other materials of the TCO layer 204 may contain zinc, indium, tin, cadmium, aluminum, copper, gallium, alloys thereof, mixtures thereof, or combinations thereof. The metal oxides include stoichiometric metal oxides, non-stoichiometric metal oxides, or mixtures thereof. Exemplary metal oxides, metal selenides, or metal tellurides which may be contained within the TCO layer 204 include zinc oxide (e.g., ZnO), indium oxide (In₂O₃), tin oxide (e.g., SnO₂), zinc tin oxide, indium tin oxide (ITO), cadmium oxide (CdO), cadmium stannate (e.g., Cd₂SnO₄), aluminum oxide or alumina (e.g., Al₂O₃), copper oxide, tungsten oxide, molybdenum oxide, nickel oxide, vanadium oxide, tungsten nickel oxide, gallium oxide, copper indium gallium selenide (CIGS—e.g., CuIn₁₋ₓGaₓSe₂-based materials, where x is within a range from about 0.001 to about 0.999), cadmium telluride (e.g., CdSe-based materials), doped materials thereof, derivatives thereof, alloys thereof, or combinations thereof. The TCO layer 204 may contain TCO materials that include additional dopants or elements, such as aluminum, gallium, boron, fluorine, sulfur, selenium, tellurium, or mixtures thereof. In some examples, the TCO layer 204 may contain zinc oxide with a dopant concentration of about 5 at % (atomic percent) or less, such as about 2.5 at % or less. In some examples, the TCO layer 204 may contain and/or be fabricated from a zinc oxide layer having a desired aluminum oxide or alumina dopant concentration formed within the zinc oxide layer. In one example, the TCO layer 204 may be doped and have zinc oxide containing aluminum at a concentration of about 2.5 at %. In another example, the TCO layer 204 may be doped and have tin oxide containing a dopant of fluorine. The TCO layer 204 generally has a thickness within a range from about 1,000 Å (1 μm) to about 20,000 Å (20 μm), more narrowly within a range from about 5,000 Å (5 μm) to about 10,000 Å (10 μm), and more narrowly within a range from about 7,000 Å (7 μm) to about 12,000 Å (12 μm).

The TCO layer 204 may be deposited or otherwise formed by a PVD process, an electroless chemical deposition/plating process, a CVD process, a PE-CVD process, or other deposition processes. In many examples, the TCO layer 204 is fabricated by a sputter deposition process, wherein the TCO material is either sputtered from a metal oxide target or sputtered from a metallic target within an oxidizing environment, such as a chamber containing oxygen, ozone, or other oxidizing agent. In some examples, the transparent substrate 202 may be provided by a supplier (e.g., glass manufacturer) with the TCO layer 204 already provided thereon. Several PVD processes which may be used to fabricate the TCO layer 204 are further described in commonly assigned U.S. application Ser. Nos. 12/748,780 and 12/748,790, both filed Mar. 29, 2010, and respectively published as U.S. Pub. Nos. 2010-0311228 and 2010-0311204, which are incorporated herein by reference.

The HWF buffer layer 250 is disposed between the TCO layer 204 and the p-type Si-based layer 212 of the first p-i-n junction 210. The HWF buffer layer 250 is deposited, plated, or otherwise formed on the TCO layer 204, and subsequently, the first p-i-n junction 210 is formed on or over the HWF buffer layer 250. An electronic barrier exists at the TCO/p-layer interface—therebetween the TCO layer 204 and the p-type Si-based layer 212—if the HWF buffer layer 250 was omitted from the tandem-type PV cell 200. However, the HWF buffer layer 250 is disposed within the TCO/p-layer interface to form a TCO/HWFL/p-layer interface, wherein the HWF buffer layer 250 is a high work-function layer (HWFL). Therefore, the electronic barrier at the TCO/HWFL/p-layer interface is eliminated or substantially reduced in the tandem-type PV cell 200 containing the HWF buffer layer 250, relative to the electronic barrier at the TCO/p-layer interface within a PV cell lacking the HWF buffer layer 250. The elimination or substantial reduction of the electronic barrier at the TCO/HWFL/p-layer interface enables the use of wider bandgap p-layer materials contained within the p-type Si-based layer 212. Also, the elimination or substantial reduction of the electronic barrier at the TCO/HWFL/p-layer interface in the tandem-type PV cell 200 provides for the use of higher carbon concentrations within the p-type materials contained within the p-type Si-based layer 212. Generally, the p-type materials that have a higher carbon concentration also have a wider bandgap energy without sacrificing the fill factor.

The HWF buffer layer 250 contains one or more high work-function materials. The high work-function materials provide the HWF buffer layer 250 with the following desired properties: (i) high work-function (e.g., <4.5 eV), (ii) optical transparency, (iii) electrical conductivity, and (iv) resistance to H₂ plasma. Generally, the high work-function materials may be stoichiometric and/or non-stoichiometric metal oxides, metal nitrides, metal oxynitrides, or mixtures thereof. Exemplary high work-function materials contained within the HWF buffer layer 250 include tungsten oxide, tungsten nitride, molybdenum oxide, molybdenum nitride, nickel oxide, nickel nitride, vanadium oxide, vanadium nitride, tungsten nickel oxide, gallium indium oxide, zinc tin oxide, zinc indium tin oxide, gallium indium tin oxide, derivatives thereof, alloys thereof, dopant variants thereof, or combinations thereof.

The HWF buffer layer 250 may exist in a variety of morphologies, such as a single layer or a bulk film, as well as multi-layered films, laminate films, film stacks, nanoparticles, and nanowires. Therefore, the HWF buffer layer 250 is deposited or otherwise formed on the TCO layer 204 by a variety of different processes including vapor deposition processes, such as CVD, ALD, PVD, or evaporation, and solution-based deposition or plating processes, such as electroless deposition and electrochemical plating. The HWF buffer layer 250 generally has a thickness within a range from about 1 Å to about 1,000 Å (1 μm), more narrowly within a range from about 20 Å to about 100 Å.

In one embodiment, the HWF buffer layer 250 contains a single layer or a bulk film of a high work-function material. In one example, the HWF buffer layer 250 contains vanadium oxide. In another example, the HWF buffer layer 250 contains nickel tungsten oxide. In other embodiments, the HWF buffer layer 250 is a multi-layered film, such as a laminate film or a film stack, and contains a plurality of layers of high work-function materials. Each of the layers within the multi-layered film may independently contain the same material or a different material as the other layers therein. The HWF buffer layer 250 as a multi-layered film may have 2 layers, 3 layers, 4 layers, 5 layers, or more layers. In some examples, the HWF buffer layer 250 contains a layer of tungsten oxide and a layer of tungsten nitride, for example, a tungsten oxide layer disposed on a tungsten nitride layer. In other examples, the HWF buffer layer 250 contains a layer of gallium indium oxide, a layer of zinc tin oxide, and a layer of tungsten oxide, for example, a gallium indium oxide layer disposed on a zinc tin oxide layer disposed on a tungsten oxide layer.

In other embodiments, the HWF buffer layer 250 contains nanoparticles or nanowires containing one or more of the high work-function materials. The HWF buffer layer 250 may contain nanoparticles having a particle size within a range from about 1 nm to about 500 nm. The HWF buffer layer 250 generally has a surface density of nanoparticles within a range from about 10 particles/μm² to about 100 particles/μm². In some examples, the HWF buffer layer 250 contains nanoparticles of tungsten oxide, vanadium oxide, or nickel tungsten oxide. Alternatively, the HWF buffer layer 250 contains nanowires having a diameter within a range from about 25 nm to about 500 nm and a length within a range from about 500 nm to about 10,000 nm (about 10 μm). The HWF buffer layer 250 generally has a surface density of the nanowires within a range from about 10 wires/μm² to about 100 wires/μm². In some examples, the HWF buffer layer 250 contains nanowires of tungsten nitride or nickel nitride.

In one example, a solar cell, such as the tandem-type PV cell 200, in which a HWFL, the HWF buffer layer 250, is disposed between a TCO layer and a Si-based p-i-n junction layer, such as between the TCO layer 204 and the first p-i-n junction 210. The HWF buffer layer 250 enhances the performance of the tandem-type PV cell 200, as opposed to a solar cell lacking a HWFL, such as by shielding the low work-function (φ) of the TCO layer 204, from the layers of the first p-i-n junction 210. This enhancement by the HWF buffer layer 250 pushes both the Fermi level and valence and conduction bands of the p-type material within the p-type Si-based layer 212 upwards in a direction to resemble ohmic contact as opposed to a Schottky/electronic barrier.

For comparison, a solar or PV cell lacking a HWFL (e.g., similar to the PV cell 100 omitting the HWF buffer layer 150) therefore has a TCO/p-Si interface. The electronic barrier that exists at the TCO/p-Si interface is due to a work-function mismatch that exists between the p-i-n Si junction and the TCO layer. The low work-function of the TCO layer pulls both the Fermi level (E_{f}) and valence and conduction bands of the p-Si layer in the direction opposite to that of an ohmic contact when the TCO and p-Si layers are placed into intimate contact with each other. Consequently, the formation of a Schottky/electronic barrier follows. However, in the tandem-type PV cell 200 containing the HWF buffer layer 250, the Schottky/electronic barrier has been eliminated or substantially reduced due to the contact between the p-type Si-based layer 212 and high work-function material of the HWF buffer layer 250.

In one embodiment, the HWF buffer layer 250 may have a work-function (φ) equal to, substantially equal to, or greater than the work-function of the p-type Si-based layer 212. The work-function of the HWF buffer layer 250 is generally within a range from about 1% to about 50% greater than the work-function of the p-type Si-based layer 212. In many examples, the work-function of the HWF buffer layer 250 is about 5 eV or greater and the work-function of the p-type Si-based layer 212 is about 5 eV or less. Typically, the work-function of the p-type Si-based layer 212 is within a range from about 4 eV to about 5 eV. Therefore, the work-function of the HWF buffer layer 250 is usually greater than 4.5 eV, such as 4.8 eV or greater and is generally within a range from about 4.8 eV to about 8 eV, more narrowly within a range from about 5 eV to about 7 eV, and more narrowly within a range from about 5.25 eV to about 6.5 eV. In some examples, the work-function of the HWF buffer layer 250 is about 5.15 eV.

Also, the electrical resistivity of the HWF buffer layer 250 is equal to, substantially equal to, or less than the electrical resistivity of the p-type Si-based layer 212, generally, the electrical resistivity of the HWF buffer layer 250 is less than 1% of the electrical resistivity of the p-type Si-based layer 212. The electrical resistivity of the HWF buffer layer 250 is typically about 1×10¹¹ μΩ·cm or less, such as within a range from about 1×10¹ μΩ·cm to about 1×10¹¹ μΩ·cm, more narrowly within a range from about 1×10² μΩ·cm to about 1×10⁸ μΩ·cm.

In some examples, the resistivity of a film containing the TCO layer 204 and the HWF buffer layer 250 is increased by about 5% or less, relative to the resistivity of the same TCO layer 204 alone (e.g., same composition and thickness). Also, the mobility of a film containing the TCO layer 204 and the HWF buffer layer 250 is decreased by about 5% or less, relative to the mobility of the same TCO layer 204 alone. Additionally, the roughness of a film containing the TCO layer 204 and the HWF buffer layer 250 is reduced by about 10% or less, relative to the roughness of the same TCO layer 204 alone. In other examples, the HWF buffer layer 250 adheres to and is in contact with an adjacent silicon-based layer or material, such as the p-type Si-based layer 212, wherein no delamination or substantially no delamination occurs between the HWF buffer layer 250 and the adjacent silicon-based layer or material (e.g., the p-type Si-based layer 212). In other examples, the HWF buffer layer 250 is resistant to or substantially resistant to the exposure of a chemically reducing plasma (e.g., hydrogen plasma) such that no transmission losses or substantially no transmission losses are attributed to the HWF buffer layer 250 post plasma exposure.

The HWF buffer layer 250 may have a refractive index (n) greater than the refractive index of the TCO layer 204 and less than the refractive index of the p-type Si-based layer 212, such that n_{TCO}<n<n_{p-Si}, for a wavelength (λ) within a range from about 350 nm to about 2,000 nm. Generally, the refractive index of the HWF buffer layer 250 is within a range from about 1% to about 125% greater than the refractive index of the first transparent metal oxide layer for a wavelength (λ) within a range from about 350 nm to about 2,000 nm. Also, the refractive index of the HWF buffer layer 250 is usually within a range from about 1% to about 55% less than the refractive index of the p-type silicon-based layer for a wavelength (λ) within a range from about 350 nm to about 2,000 nm. Therefore, the refractive index of the HWF buffer layer 250 is within a range from about 1.5 to about 4.5 for a wavelength (λ) within a range from about 350 nm to about 2,000 nm.

The absorption coefficient (α) of the HWF buffer layer 250 is less than the absorption coefficient of the TCO layer 204 for a wavelength (λ) within a range from about 350 nm to about 2,000 nm. The absorption coefficient of the HWF buffer layer 250 is no less than 1% of the absorption coefficient of the TCO layer 204 for a wavelength (λ) within a range from about 350 nm to about 2,000 nm. The absorption coefficient of the HWF buffer layer 250 is typically within a range from about 1×10⁻² cm⁻¹ to about 1×10⁶ cm⁻¹, more narrowly within a range from about 1×10⁻¹ cm⁻¹ to about 1×10⁵ cm⁻¹, for a wavelength (λ) within a range from about 350 nm to about 2,000 nm. The HWF buffer layer 250 may have a transmission value of about 95% or greater, such as about 96% or greater, such as about 97% or greater, such as about 98% or greater, such as about 99% or greater, for example, about 99.5% or greater for a wavelength (λ) within a range from about 350 nm to about 2,000 nm.

The p-type Si-based layer 212 contains a silicon-based material such as amorphous silicon (α-Si), polycrystalline silicon (poly-Si), microcrystalline silicon (μc-Si), or combinations thereof, which is doped by a Group III element. In many examples, the silicon-based materials contained within the p-type Si-based layer 212 are amorphous silicon materials. The silicon-based material, layer, or film doped with the Group III element is referred to as a p-doped or a p-type silicon material, layer, or film. The p-type Si-based layer 212 also contains at least one dopant element and may contain two or more dopant elements, such as boron, gallium, carbon, or combinations thereof. In many examples, the p-type Si-based layer 212 contains a boron-doped, amorphous silicon material or a boron-doped, carbon-doped, amorphous silicon material. Alternatively, the p-type Si-based layer 212 may be doped with other elements selected to meet device requirements of the tandem-type PV cell 200. In some examples, the p-type Si-based layer 212 contains a silicon-based material doped with carbon and has a carbon concentration within a range from about 0.01 at % to about 50 at %, more narrowly within a range from about 0.1 at % to about 20 at %, more narrowly within a range from about 1 at % to about 10 at %, and more narrowly within a range from about 2 at % to about 5 at %. The p-type Si-based layer 212 is generally deposited by CVD or PE-CVD. The p-type Si-based layer 212 generally has a thickness within a range from about 1 Å to about 500 Å, more narrowly within a range from about 10 Å to about 200 Å, and more narrowly within a range from about 20 Å to about 50 Å.

The intrinsic Si-based layer 214 is a non-doped type silicon based film disposed between the p-type Si-based layer 212 and the n-type Si-based layer 216. The intrinsic Si-based layer 214 is deposited under process conditions controlled to provide film properties having improved photoelectric conversion efficiency of the tandem-type PV cell 200. In many examples, the intrinsic Si-based layer 214 contains and is fabricated from an intrinsic (i-type) material, such as i-type polycrystalline silicon (poly-Si), i-type microcrystalline silicon (μc-Si), amorphous silicon (α-Si), or hydrogenated amorphous silicon (α-Si:H). The intrinsic Si-based layer 214 generally has a thickness within a range from about 100 Å and about 100,000 Å (100 μm) depending on the application and the type of silicon-based material. In one embodiment, the intrinsic Si-based layer 214 contains amorphous silicon and has a thickness within a range from about 100 Å Å to about 10,000 Å (10 μm), more narrowly within a range from about 200 Å to about 8,000 Å (8 μm), and more narrowly within a range from about 1,000 Å (1 μm) to about 5,000 Å (5 μm). In another embodiment, the intrinsic Si-based layer 214 contains microcrystalline silicon and has a thickness within a range from about 1,000 Å (1 μm) to about 100,000 Å (100 μm), more narrowly within a range from about 2,000 Å (2 μm) to about 80,000 Å (80 μm), and more narrowly within a range from about 10,000 Å (10 μm) to about 50,000 Å (50 μm).

The n-type Si-based layer 216 contains a silicon-based material such as amorphous silicon (α-Si), polycrystalline silicon (poly-Si), microcrystalline silicon (μc-Si), or combinations thereof, which is doped by a Group V element. In many examples, the n-type Si-based layer 216 contains n-doped amorphous silicon. The silicon-based material, layer, or film doped with the Group V element is referred to as an n-doped or an n-type silicon material, layer, or film. The n-type Si-based layer 216 also contains at least one dopant element and may contain two or more dopant elements, such as phosphorous, arsenic, or combinations thereof. In one example, the n-type Si-based layer 216 contains a phosphorus doped, amorphous silicon material. Alternatively, the n-type Si-based layer 216 may be doped with other elements selected to meet device requirements of the tandem-type PV cell 200. The n-type Si-based layer 216 is generally deposited by CVD or PE-CVD. The n-type Si-based layer 216 typically has a thickness within a range from about 1 Å to about 500 Å, more narrowly within a range from about 10 Å to about 200 Å, and more narrowly within a range from about 30 Å to about 70 Å.

In one embodiment, an intermediate TCO layer 218 and the HWF buffer layer 260 are disposed between the first p-i-n junction 210 and the second p-i-n junction 220. The intermediate TCO layer 218 contains a TCO material or layer and is deposited or otherwise formed on the first p-i-n junction 210. Thereafter, the HWF buffer layer 260 is deposited or otherwise formed on the intermediate TCO layer 218 and subsequently, the second p-i-n junction 220 is formed on the HWF buffer layer 260. The combination of the first p-i-n junction 210, the HWF buffer layer 260, and the second p-i-n junction 220, as depicted in FIG. 2, increases the overall photoelectric conversion efficiency of the tandem-type PV cell 200 in some embodiments described herein.

The intermediate TCO layer 218 may be independently fabricated or contain the same material or a different material as the TCO layer 204. The intermediate TCO layer 218 may contain a metal oxide, a mixture of metal oxides, a metal selenide, a metal telluride, or a mixture thereof that is electrically conductive and transparent. The metal oxides or other materials of the intermediate TCO layer 218 may contain zinc, indium, tin, cadmium, aluminum, copper, gallium, alloys thereof, mixtures thereof, or combinations thereof. The metal oxides include stoichiometric metal oxides, non-stoichiometric metal oxides, or mixtures thereof. Exemplary metal oxides, metal selenides, or metal tellurides which may be contained within the intermediate TCO layer 218 include zinc oxide (e.g., ZnO), indium oxide (In₂O₃), tin oxide (e.g., SnO₂), zinc tin oxide, indium tin oxide (ITO), cadmium oxide (CdO), cadmium stannate (e.g., Cd₂SnO₄), aluminum oxide or alumina (e.g., Al₂O₃), copper oxide, tungsten oxide, molybdenum oxide, nickel oxide, vanadium oxide, tungsten nickel oxide, gallium oxide, copper indium gallium selenide (CIGS—e.g., CuIn₁₋ₓGaₓSe₂-based materials, where x is within a range from about 0.001 to about 0.999), cadmium telluride (e.g., CdSe-based materials), doped materials thereof, derivatives thereof, alloys thereof, or combinations thereof.

The intermediate TCO layer 218 may contain TCO materials that include additional dopants or elements, such as aluminum, gallium, boron, fluorine, sulfur, selenium, tellurium, or mixtures thereof. In some examples, the intermediate TCO layer 218 may contain zinc oxide with a dopant concentration of about 5 at % (atomic percent) or less, such as about 2.5 at % or less. In some examples, the intermediate TCO layer 218 may contain and/or be fabricated from a zinc oxide layer having a desired aluminum oxide or alumina dopant concentration formed within the zinc oxide layer. In one example, the intermediate TCO layer 218 may be doped and have zinc oxide containing aluminum at a concentration of about 2.5 at %. In another example, the intermediate TCO layer 218 may be doped and have tin oxide containing a dopant of fluorine. The intermediate TCO layer 218 generally has a thickness within a range from about 1,000 Å (1 μm) to about 20,000 Å (20 μm), more narrowly within a range from about 5,000 Å (5 μm) to about 10,000 Å (10 μm), and more narrowly within a range from about 7,000 Å (7 μm) to about 12,000 Å (12 μm).

The intermediate TCO layer 218 may be deposited or otherwise formed by a PVD process, an electroless chemical deposition/plating process, a CVD process, a PE-CVD process, or other deposition processes. In many examples, the intermediate TCO layer 218 is fabricated by a sputter deposition process, wherein the TCO material is either sputtered from a metal oxide target or sputtered from a metallic target within an oxidizing environment, such as a chamber containing oxygen, ozone, or other oxidizing agent. In some examples, the transparent substrate 202 may be provided by a supplier (e.g., glass manufacturer) with the intermediate TCO layer 218 already provided thereon. Several PVD processes which may be used to fabricate the intermediate TCO layer 218 are further described in commonly assigned U.S. application Ser. Nos. 12/748,780 and 12/748,790, both filed Mar. 29, 2010, and respectively published as U.S. Pub. Nos. 2010-0311228 and 2010-0311204, which are incorporated herein by reference.

The HWF buffer layer 260 is disposed between the TCO layer 218 and the p-type Si-based layer 222 of the second p-i-n junction 220. The HWF buffer layer 260 is deposited, plated, or otherwise formed on the TCO layer 218, and subsequently, the second p-i-n junction 220 is formed on or over the HWF buffer layer 260. An electronic barrier exists at the TCO/p-layer interface—therebetween the TCO layer 218 and the p-type Si-based layer 222—if the HWF buffer layer 260 was omitted from the tandem-type PV cell 200. However, the HWF buffer layer 260 is disposed within the TCO/p-layer interface to form a TCO/HWFL/p-layer interface, wherein the HWF buffer layer 260 is a HWFL. Therefore, the electronic barrier at the TCO/HWFL/p-layer interface is eliminated or substantially reduced in the tandem-type PV cell 200 containing the HWF buffer layer 260, relative to the electronic barrier at the TCO/p-layer interface within a PV cell lacking the HWF buffer layer 260. The elimination or substantial reduction of the electronic barrier at the TCO/HWFL/p-layer interface enables the use of wider bandgap p-layer materials contained within the p-type Si-based layer 222. Also, the elimination or substantial reduction of the electronic barrier at the TCO/HWFL/p-layer interface in the tandem-type PV cell 200 provides for the use of higher carbon concentrations within the p-type materials contained within the p-type Si-based layer 222. Generally, the p-type materials that have a higher carbon concentration also have a wider bandgap energy without sacrificing the fill factor.

The HWF buffer layer 260 contains one or more high work-function materials. The high work-function materials provide the HWF buffer layer 260 with the following desired properties: (i) high work-function (e.g., <4.5 eV), (ii) optical transparency, (iii) electrical conductivity, and (iv) resistance to H₂ plasma. Generally, the high work-function materials may be stoichiometric and/or non-stoichiometric metal oxides, metal nitrides, metal oxynitrides, or mixtures thereof. Exemplary high work-function materials contained within the HWF buffer layer 260 include tungsten oxide, tungsten nitride, molybdenum oxide, molybdenum nitride, nickel oxide, nickel nitride, vanadium oxide, vanadium nitride, tungsten nickel oxide, gallium indium oxide, zinc tin oxide, zinc indium tin oxide, gallium indium tin oxide, derivatives thereof, alloys thereof, dopant variants thereof, or combinations thereof.

The HWF buffer layer 260 may exist in a variety of morphologies, such as a single layer or a bulk film, as well as multi-layered films, laminate films, film stacks, nanoparticles, and nanowires. Therefore, the HWF buffer layer 260 is deposited or otherwise formed on the intermediate TCO layer 218 by a variety of different processes including vapor deposition processes, such as CVD, ALD, PVD, or evaporation, and solution-based deposition or plating processes, such as electroless deposition and electrochemical plating. The HWF buffer layer 260 generally has a thickness within a range from about 1 Å to about 1,000 Å (1 μm), more narrowly within a range from about 20 Å to about 100 Å.

In one embodiment, the HWF buffer layer 260 contains a single layer or a bulk film of a high work-function material. In one example, the HWF buffer layer 260 contains vanadium oxide. In another example, the HWF buffer layer 260 contains nickel tungsten oxide. In other embodiments, the HWF buffer layer 260 is a multi-layered film, such as a laminate film or a film stack, and contains a plurality of layers of high work-function materials. Each of the layers within the multi-layered film may independently contain the same material or a different material as the other layers therein. The HWF buffer layer 260 as a multi-layered film may have 2 layers, 3 layers, 4 layers, 5 layers, or more layers. In some examples, the HWF buffer layer 260 contains a layer of tungsten oxide and a layer of tungsten nitride, for example, a tungsten oxide layer disposed on a tungsten nitride layer. In other examples, the HWF buffer layer 260 contains a layer of gallium indium oxide, a layer of zinc tin oxide, and a layer of tungsten oxide, for example, a gallium indium oxide layer disposed on a zinc tin oxide layer disposed on a tungsten oxide layer.

In other embodiments, the HWF buffer layer 260 contains nanoparticles or nanowires containing one or more of the high work-function materials. The HWF buffer layer 260 may contain nanoparticles having a particle size within a range from about 1 nm to about 500 nm. The HWF buffer layer 260 generally has a surface density of nanoparticles within a range from about 10 particles/μm² to about 100 particles/μm². In some examples, the HWF buffer layer 260 contains nanoparticles of tungsten oxide, vanadium oxide, or nickel tungsten oxide. Alternatively, the HWF buffer layer 260 contains nanowires having a diameter within a range from about 25 nm to about 500 nm and a length within a range from about 500 nm to about 10,000 nm (about 10 μm). The HWF buffer layer 260 generally has a surface density of the nanowires within a range from about 10 wires/μm² to about 100 wires/μm². In some examples, the HWF buffer layer 260 contains nanowires of tungsten nitride or nickel nitride.

In one example, a solar cell, such as the tandem-type PV cell 200, in which a HWFL, the HWF buffer layer 260, is disposed between a TCO layer and a Si-based p-i-n junction layer, such as between the TCO layer 218 and the second p-i-n junction 220. The HWF buffer layer 260 enhances the performance of the tandem-type PV cell 200, as opposed to a solar cell lacking a HWFL, such as by shielding the low work-function (φ) of the TCO layer 218, from the layers of the second p-i-n junction 220. This enhancement by the HWF buffer layer 260 pushes both the Fermi level and valence and conduction bands of the p-type material within the p-type Si-based layer 222 upwards in a direction to resemble ohmic contact as opposed to a Schottky/electronic barrier.

For comparison, a solar or PV cell lacking a HWFL (e.g., similar to the PV cell 100 omitting the HWF buffer layer 150) therefore has a TCO/p-Si interface. The electronic barrier that exists at the TCO/p-Si interface is due to a work-function mismatch that exists between the p-i-n Si junction and the TCO layer. The low work-function of the TCO layer pulls both the Fermi level (E_{f}) and valence and conduction bands of the p-Si layer in the direction opposite to that of an ohmic contact when the TCO and p-Si layers are placed into intimate contact with each other. Consequently, the formation of a Schottky/electronic barrier follows. However, in the tandem-type PV cell 200 containing the HWF buffer layer 260, the Schottky/electronic barrier has been eliminated or substantially reduced due to the contact between the p-type Si-based layer 222 and high work-function material of the HWF buffer layer 260.

The work-function (φ) of the HWF buffer layer 260 is equal to, substantially equal to, or greater than the work-function of the p-type Si-based layer 222. The work-function of the HWF buffer layer 260 is generally within a range from about 1% to about 50% greater than the work-function of the p-type Si-based layer 222. In many examples, the work-function of the HWF buffer layer 260 is about 5 eV or greater and the work-function of the p-type Si-based layer 222 is about 5 eV or less. Typically, the work-function of the p-type Si-based layer 222 is within a range from about 4 eV to about 5 eV. Therefore, the work-function of the HWF buffer layer 260 is usually greater than 4.5 eV, such as 4.8 eV or greater and is generally within a range from about 4.8 eV to about 8 eV, more narrowly within a range from about 5 eV to about 7 eV, and more narrowly within a range from about 5.25 eV to about 6.5 eV. In some examples, the work-function of the HWF buffer layer 260 is about 5.15 eV.

Also, the electrical resistivity of the HWF buffer layer 260 is equal to, substantially equal to, or less than the electrical resistivity of the p-type Si-based layer 222, generally, the electrical resistivity of the HWF buffer layer 260 is less than 1% of the electrical resistivity of the p-type Si-based layer 222. The electrical resistivity of the HWF buffer layer 260 is typically about 1×10¹¹ μΩ·cm or less, such as within a range from about 1×10¹ μΩ·cm to about 1×10¹¹ μΩ·cm, more narrowly within a range from about 1×10² μΩ·cm to about 1×10⁸ μΩ·cm.

In some examples, the resistivity of a film containing the intermediate TCO layer 218 and the HWF buffer layer 260 is increased by about 5% or less, relative to the resistivity of the same intermediate TCO layer 218 alone (e.g., same composition and thickness). Also, the mobility of a film containing the intermediate TCO layer 218 and the HWF buffer layer 260 is decreased by about 5% or less, relative to the mobility of the same intermediate TCO layer 218 alone. Additionally, the roughness of a film containing the intermediate TCO layer 218 and the HWF buffer layer 260 is reduced by about 10% or less, relative to the roughness of the same intermediate TCO layer 218 alone. In other examples, the HWF buffer layer 260 adheres to and is in contact with an adjacent silicon-based layer or material, such as the p-type Si-based layer 222, wherein no delamination or substantially no delamination occurs between the HWF buffer layer 260 and the adjacent silicon-based layer or material (e.g., the p-type Si-based layer 222). In other examples, the HWF buffer layer 260 is resistant to or substantially resistant to the exposure of a chemically reducing plasma (e.g., hydrogen plasma) such that no transmission losses or substantially no transmission losses are attributed to the HWF buffer layer 260 post plasma exposure.

The HWF buffer layer 260 may have a refractive index (n) greater than the refractive index of the intermediate TCO layer 218 and less than the refractive index of the p-type Si-based layer 222, such that n_{TCO}<n<n_{p-Si}, for a wavelength (λ) within a range from about 350 nm to about 2,000 nm. Generally, the refractive index of the HWF buffer layer 260 is within a range from about 1% to about 125% greater than the refractive index of the first transparent metal oxide layer for a wavelength (λ) within a range from about 350 nm to about 2,000 nm. Also, the refractive index of the HWF buffer layer 260 is usually within a range from about 1% to about 55% less than the refractive index of the p-type silicon-based layer for a wavelength (λ) within a range from about 350 nm to about 2,000 nm. Therefore, the refractive index of the HWF buffer layer 260 is within a range from about 1.5 to about 4.5 for a wavelength (λ) within a range from about 350 nm to about 2,000 nm.

The absorption coefficient (α) of the HWF buffer layer 260 is less than the absorption coefficient of the intermediate TCO layer 218 for a wavelength (λ) within a range from about 350 nm to about 2,000 nm. The absorption coefficient of the HWF buffer layer 260 is no less than 1% of the absorption coefficient of the intermediate TCO layer 218 for a wavelength (λ) within a range from about 350 nm to about 2,000 nm. The absorption coefficient of the HWF buffer layer 260 is typically within a range from about 1×10⁻² cm⁻¹ to about 1×10⁶ cm⁻¹, more narrowly within a range from about 1×10⁻¹ cm⁻¹ to about 1×10⁵ cm⁻¹, for a wavelength (λ) within a range from about 350 nm to about 2,000 nm. The HWF buffer layer 260 may have a transmission value of about 95% or greater, such as about 96% or greater, such as about 97% or greater, such as about 98% or greater, such as about 99% or greater, for example, about 99.5% or greater for a wavelength (λ) within a range from about 350 nm to about 2,000 nm.

In some examples, the resistivity of a film containing the intermediate TCO layer 218 and the HWF buffer layer 260 is increased by about 5% or less, relative to the resistivity of the same intermediate TCO layer 218 alone (e.g., same composition and thickness). Also, the mobility of a film containing the intermediate TCO layer 218 and the HWF buffer layer 260 is decreased by about 5% or less, relative to the mobility of the same Intermediate TCO layer 218 alone. Additionally, the roughness of a film containing the intermediate TCO layer 218 and the HWF buffer layer 260 is reduced by about 10% or less, relative to the roughness of the same Intermediate TCO layer 218 alone. In other examples, the HWF buffer layer 260 adheres to and is in contact with an adjacent silicon-based layer or material, such as the p-type Si-based layer 222, wherein no delamination or substantially no delamination occurs between the HWF buffer layer 260 and the adjacent silicon-based layer or material (e.g., the p-type Si-based layer 222). In other examples, the HWF buffer layer 260 is resistant to or substantially resistant to the exposure of a chemically reducing plasma (e.g., hydrogen plasma) such that no transmission losses or substantially no transmission losses are attributed to the HWF buffer layer 260 post plasma exposure.

The second p-i-n junction 220 contains the intrinsic Si-based layer 224 disposed between the p-type Si-based layer 222 and the n-type Si-based layer 226, as depicted in FIG. 2. The p-type Si-based layer 222, the intrinsic Si-based layer 224, and the n-type Si-based layer 226 each independently may contain μc-Si based materials, polysilicon-based materials, amorphous Si-based materials, and/or a combination thereof. In many examples, the second p-i-n junction 220 a μc-Si film as the intrinsic Si-based layer 224 disposed between a p-type amorphous Si-based layer 222 and an n-type amorphous Si-based layer 226.

The p-type Si-based layer 222 contains a silicon-based material such as amorphous silicon (α-Si), polycrystalline silicon (poly-Si), microcrystalline silicon (μc-Si), or combinations thereof, which is doped by a Group III element. In many examples, the silicon-based materials contained within the p-type Si-based layer 222 are amorphous silicon materials. The silicon-based material, layer, or film doped with the Group III element is referred to as a p-doped or a p-type silicon material, layer, or film. The p-type Si-based layer 222 also contains at least one dopant element and may contain two or more dopant elements, such as boron, gallium, carbon, or combinations thereof. In many examples, the p-type Si-based layer 222 contains a boron-doped, amorphous silicon material or a boron-doped, carbon-doped, amorphous silicon material. Alternatively, the p-type Si-based layer 222 may be doped with other elements selected to meet device requirements of the tandem-type PV cell 200. In some examples, the p-type Si-based layer 222 contains a silicon-based material doped with carbon and has a carbon concentration within a range from about 0.01 at % to about 50 at %, more narrowly within a range from about 0.1 at % to about 20 at %, more narrowly within a range from about 1 at % to about 10 at %, and more narrowly within a range from about 2 at % to about 5 at %. The p-type Si-based layer 222 is generally deposited by CVD or PE-CVD. The p-type Si-based layer 222 generally has a thickness within a range from about 1 Å to about 500 Å, more narrowly within a range from about 10 Å to about 200 Å, and more narrowly within a range from about 20 Å to about 50 Å.

The intrinsic Si-based layer 224 is a non-doped type silicon based film disposed between the p-type Si-based layer 222 and the n-type Si-based layer 226. The intrinsic Si-based layer 224 is deposited under process conditions controlled to provide film properties having improved photoelectric conversion efficiency of the tandem-type PV cell 200. In many examples, the intrinsic Si-based layer 224 contains and is fabricated from an intrinsic (i-type) material, such as i-type polycrystalline silicon (poly-Si), i-type microcrystalline silicon (μc-Si), amorphous silicon (α-Si), or hydrogenated amorphous silicon (α-Si:H). The intrinsic Si-based layer 224 generally has a thickness within a range from about 100 Å and about 100,000 Å (100 μm) depending on the application and the type of silicon-based material. In one embodiment, the intrinsic Si-based layer 224 contains amorphous silicon and has a thickness within a range from about 100 Å to about 10,000 Å (10 μm), more narrowly within a range from about 200 Å to about 8,000 Å (8 μm), and more narrowly within a range from about 1,000 Å (1 μm) to about 5,000 Å (5 μm). In another embodiment, the intrinsic Si-based layer 224 contains microcrystalline silicon and has a thickness within a range from about 1,000 Å (1 μm) to about 100,000 Å (100 μm), more narrowly within a range from about 2,000 Å (2 μm) to about 80,000 Å (80 μm), and more narrowly within a range from about 10,000 Å (10 μm) to about 50,000 Å (50 μm).

The n-type Si-based layer 226 contains a silicon-based material such as amorphous silicon (α-Si), polycrystalline silicon (poly-Si), microcrystalline silicon (μc-Si), or combinations thereof, which is doped by a Group V element. In many examples, the n-type Si-based layer 226 contains n-doped amorphous silicon. The silicon-based material, layer, or film doped with the Group V element is referred to as an n-doped or an n-type silicon material, layer, or film. The n-type Si-based layer 226 also contains at least one dopant element and may contain two or more dopant elements, such as phosphorous, arsenic, or combinations thereof. In one example, the n-type Si-based layer 226 contains a phosphorus doped, amorphous silicon material. Alternatively, the n-type Si-based layer 226 may be doped with other elements selected to meet device requirements of the tandem-type PV cell 200. The n-type Si-based layer 226 is generally deposited by CVD or PE-CVD. The n-type Si-based layer 226 typically has a thickness within a range from about 1 Å to about 500 A, more narrowly within a range from about 10 Å to about 200 Å, and more narrowly within a range from about 30 Å to about 70 Å.

A back reflector 230 is fabricated or otherwise formed on or over the second p-i-n junction 220. The back reflector 230 contains a metallic reflective layer 234 disposed on or over a TCO layer 232. The TCO layer 232 is deposited or otherwise formed on the second p-i-n junction 220, such as on the n-type Si-based layer 226. Thereafter, the metallic reflective layer 234 is deposited or otherwise formed on the TCO layer 232. The materials of the TCO layer 232 and the metallic reflective layer 234 may be the same materials, substantially the same materials, or different materials as in the TCO layer 132 and the metallic reflective layer 134, respectively, as depicted FIG. 1. Also, the TCO layer 232 may be independently fabricated or contain the same materials, substantially the same materials, or different materials as the TCO layer 204 or the intermediate TCO layer 218.

The TCO layer 232 may contain a metal oxide, a mixture of metal oxides, a metal selenide, a metal telluride, or a mixture thereof that is electrically conductive and transparent. The metal oxides or other materials of the TCO layer 232 may contain zinc, indium, tin, cadmium, aluminum, copper, gallium, alloys thereof, mixtures thereof, or combinations thereof. The metal oxides include stoichiometric metal oxides, non-stoichiometric metal oxides, or mixtures thereof. Exemplary metal oxides, metal selenides, or metal tellurides which may be contained within the TCO layer 232 include zinc oxide (e.g., ZnO), indium oxide (In₂O₃), tin oxide (e.g., SnO₂), zinc tin oxide, indium tin oxide (ITO), cadmium oxide (CdO), cadmium stannate (e.g., Cd₂SnO₄), aluminum oxide or alumina (e.g., Al₂O₃), copper oxide, tungsten oxide, molybdenum oxide, nickel oxide, vanadium oxide, tungsten nickel oxide, gallium oxide, copper indium gallium selenide (CIGS—e.g., CuIn₁,GaₓSe₂-based materials, where x is within a range from about 0.001 to about 0.999), cadmium telluride (e.g., CdSe-based materials), doped materials thereof, derivatives thereof, alloys thereof, or combinations thereof.

The TCO layer 232 may contain TCO materials that include additional dopants or elements, such as aluminum, gallium, boron, fluorine, sulfur, selenium, tellurium, or mixtures thereof. In some examples, the TCO layer 232 may contain zinc oxide with a dopant concentration of about 5 at % (atomic percent) or less, such as about 2.5 at % or less. In some examples, the TCO layer 232 may contain and/or be fabricated from a zinc oxide layer having a desired aluminum oxide or alumina dopant concentration formed within the zinc oxide layer. In one example, the TCO layer 232 may be doped and have zinc oxide containing aluminum at a concentration of about 2.5 at %. In another example, the TCO layer 232 may be doped and have tin oxide containing a dopant of fluorine. The TCO layer 232 generally has a thickness within a range from about 1,000 Å (1 μm) to about 20,000 Å (20 μm), more narrowly within a range from about 5,000 Å (5 μm) to about 10,000 Å (10 μm), and more narrowly within a range from about 7,000 Å (7 μm) to about 12,000 Å (12 μm).

The TCO layer 232 may be deposited or otherwise formed by a PVD process, an electroless chemical deposition/plating process, a CVD process, a PE-CVD process, or other deposition processes. In many examples, the TCO layer 232 is fabricated by a sputter deposition process, wherein the TCO material is either sputtered from a metal oxide target or sputtered from a metallic target within an oxidizing environment, such as a chamber containing oxygen, ozone, or other oxidizing agent. In some examples, the transparent substrate 202 may be provided by a supplier (e.g., glass manufacturer) with the TCO layer 232 already provided thereon. Several PVD processes which may be used to fabricate the TCO layer 232 are further described in commonly assigned U.S. application Ser. Nos. 12/748,780 and 12/748,790, both filed Mar. 29, 2010, and respectively published as U.S. Pub. Nos. 2010-0311228 and 2010-0311204, which are incorporated herein by reference.

The metallic reflective layer 234 contained within back reflector 130 may be deposited or otherwise formed on or over the TCO layer 232. The metallic reflective layer 234 may be formed by a PVD process, a CVD process, a PE-CVD process, an electrochemical deposition process, an electroless deposition process, or a combination of two or more deposition or plating processes. The metallic reflective layer 234 may contain or be made from at least one metal, such as titanium, chromium, aluminum, nickel, silver, gold, copper, platinum, palladium, ruthenium, alloys thereof, or combinations thereof.

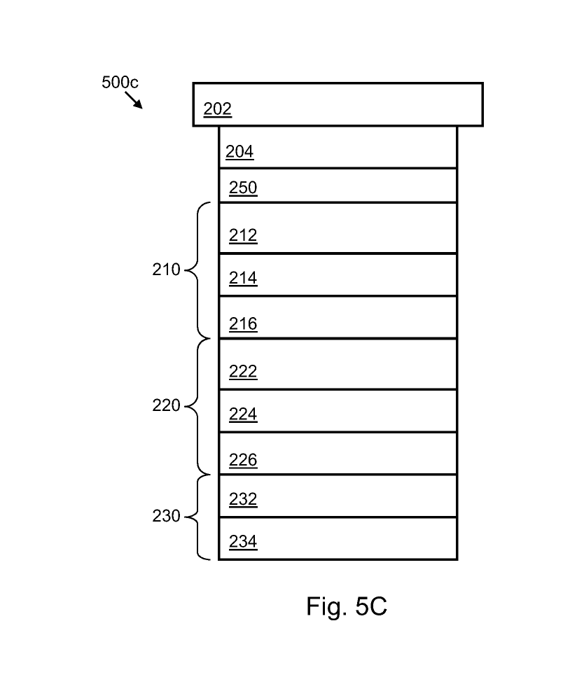

In alternative embodiments, other tandem-type PV cells that have a single HWFL, similar to the tandem-type PV cell 200, but lacking the HWF buffer layer 260. FIGS. 5A-5C depict tandem-type PV cells 500a-500c, which are similar to the tandem-type PV cell 200 and share common layers/films/materials as the same common drawing elements described herein for FIG. 2. However, tandem-type PV cells 500a-500c lack a second HWFL, such as the HWF buffer layer 260. Also, tandem-type PV cells 500b-500c lack an intermediate TCO layer, such as the intermediate TCO layer 218. Therefore, each of the tandem-type PV cells 500a-500c have a transparent substrate 202, a TCO layer, a HWF buffer layer 250, a first p-i-n junction 210, a second p-i-n junction 220, and a back reflector 230 as previously described for the tandem-type PV cell 200.

FIG. 5A depicts the tandem-type PV cell 500a that has the intermediate TCO layer 218 disposed on the first p-i-n junction 210 and the second p-i-n junction 220 disposed on the intermediate TCO layer 218, as described by one embodiment herein. Therefore, the intermediate TCO layer 218 is in contact with and disposed between the n-type Si-based layer 216 of the first p-i-n junction 210 and the p-type Si-based layer 222 of the second p-i-n junction 220.

FIG. 5B depicts the tandem-type PV cell 500b that has an interlayer 550 disposed on the first p-i-n junction 210 and the second p-i-n junction 220 disposed on the interlayer 550, as described by another embodiment herein. Therefore, the intermediate TCO layer 218 is in contact with and disposed between the n-type Si-based layer 216 of the first p-i-n junction 210 and the p-type Si-based layer 222 of the second p-i-n junction 220. The interlayer 550 is utilized to reflect blue light (λ=about 390 nm to about 500 nm) towards and into the first p-i-n junction 210 and/or red light (λ=about 600 nm to about 780 nm) towards and into the second p-i-n junction 220. The interlayer 550 contains at least one electrically non-conducting material. In one example, the interlayer 550 contains non-stoichiometric silicon oxide. The interlayer 550 generally has a thickness within a range from about 500 Å to about 5,000 Å (5 μm), more narrowly within a range from about 1,000 Å (1 μm) to about 3,000 Å (3 μm).

FIG. 5C depicts the tandem-type PV cell 500c that has the second p-i-n junction 220 disposed directly on the first p-i-n junction 210, as described by another embodiment herein. Therefore, the n-type Si-based layer 216 of the first p-i-n junction 210 is in contact with the p-type Si-based layer 222 of the second p-i-n junction 220.

While the foregoing is directed to embodiments of the invention, other and further embodiments of the invention may be devised without departing from the basic scope thereof, and the scope thereof is determined by the claims that follow.

1. A photovoltaic device, comprising:
a transparent substrate;
a first transparent metal oxide layer disposed on the transparent substrate;
a high work-function buffer layer disposed on the first transparent metal oxide layer;
a p-i-n junction disposed on the high work-function buffer layer, wherein the p-i-n junction comprises an intrinsic layer disposed between a p-type silicon-based layer and an n-type silicon-based layer, and the p-type silicon-based layer is in contact with the high work-function buffer layer;
a second transparent metal oxide layer disposed on the n-type silicon-based layer; and
a metallic reflective layer disposed on the second transparent metal oxide layer.

2. The photovoltaic device of claim 1, wherein the work-function of the high work-function buffer layer is equal to or greater than the work-function of the p-type silicon-based layer.

3. The photovoltaic device of claim 1, wherein the refractive index of the high work-function buffer layer is greater than the refractive index of the first transparent metal oxide layer and less than the refractive index of the p-type silicon-based layer for a wavelength within a range from about 350 nm to about 2,000 nm.

4. The photovoltaic device of claim 1, wherein the absorption coefficient of the high work-function buffer layer is less than the absorption coefficient of the first transparent metal oxide layer for a wavelength within a range from about 350 nm to about 2,000 nm.

5. The photovoltaic device of claim 1, wherein the high work-function buffer layer has a transmission of about 95% or greater for a wavelength within a range from about 350 nm to about 2,000 nm.

6. The photovoltaic device of claim 1, wherein the electrical resistivity of the high work-function buffer layer is equal to or less than the electrical resistivity of the p-type silicon-based layer, wherein the electrical resistivity of the high work-function buffer layer is about 1×10¹¹ μΩ·cm or less.

7. The photovoltaic device of claim 1, wherein the high work-function buffer layer comprises a material selected from the group consisting of tungsten oxide, tungsten nitride, molybdenum oxide, molybdenum nitride, nickel oxide, nickel nitride, vanadium oxide, vanadium nitride, tungsten nickel oxide, gallium indium oxide, zinc tin oxide, zinc indium tin oxide, gallium indium tin oxide, derivatives thereof, alloys thereof, dopant variants thereof, and combinations thereof.

8. The photovoltaic device of claim 1, wherein the high work-function buffer layer has a thickness within a range from about 20 Å to about 100 Å and contains a single layer, a bulk film of a high work-function material, or a multi-layered film comprising a plurality of layers.

9. The photovoltaic device of claim 1, wherein the high work-function buffer layer comprises nanoparticles or nanowires.

10. The photovoltaic device of claim 1, wherein the p-type silicon-based layer comprises carbon and has a carbon concentration within a range from about 1 at % to about 10 at % and has a thickness within a range from about 10 Å to about 200 Å.

11. The photovoltaic device of claim 1, wherein the first transparent metal oxide layer comprises a metal oxide selected from the group consisting of zinc oxide, indium oxide, tin oxide, cadmium oxide, aluminum oxide, copper oxide, gallium oxide, tungsten oxide, molybdenum oxide, nickel oxide, vanadium oxide, tungsten nickel oxide, zinc tin oxide, derivatives thereof, alloys thereof, dopant variants thereof, and combinations thereof.

12. The photovoltaic device of claim 1, wherein the n-type silicon-based layer comprises a dopant selected from phosphorous, arsenic, and combinations thereof.

13. The photovoltaic device of claim 1, wherein the intrinsic layer is a silicon-based intrinsic layer and comprises a material selected from the group consisting of polycrystalline silicon (poly-Si), microcrystalline silicon (μc-Si), amorphous silicon (α-Si), hydrogenated amorphous silicon (α-Si:H), derivatives thereof, and combinations thereof.

14. A photovoltaic device, comprising:
a transparent substrate;
a first transparent metal oxide layer disposed on the transparent substrate;
a high work-function buffer layer disposed on the first transparent metal oxide layer;
a p-i-n junction comprising a p-type silicon-based layer disposed on the high work-function buffer layer, wherein the work-function of the high work-function buffer layer is equal to or greater than the work-function of the p-type silicon-based layer;
a second transparent metal oxide layer disposed on the p-i-n junction; and
a metallic reflective layer disposed on the second transparent metal oxide layer.

15. A photovoltaic device, comprising:
a transparent substrate;
a first transparent metal oxide layer disposed on the transparent substrate;
a first high work-function buffer layer disposed on the first transparent metal oxide layer;
a first p-i-n junction disposed on the first high work-function buffer layer;
a second transparent metal oxide layer disposed on the first p-i-n junction;
a second high work-function buffer layer disposed on the second transparent metal oxide layer;
a second p-i-n junction disposed on the second high work-function buffer layer;
a third transparent metal oxide layer disposed on the second p-i-n junction; and
a metallic reflective layer disposed on the third transparent metal oxide layer.
